(19) United States
(12) Patent Application Publication
(10) Pub. No.: US 2013/0147003 A1
(43) Pub. Date: Jun. 13, 2013

(54) PHOTOVOLTAIC DEVICE

(71) Applicants: Young-Su KIM, Yongin-si (KR); Chan-Bin Mo, Yongin-si (KR)

(72) Inventors: Young-Su KIM, Yongin-si (KR); Chan-Bin Mo, Yongin-si (KR)

(21) Appl. No.: 13/584,917

(22) Filed: Aug. 14, 2012

Related U.S. Application Data
(60) Provisional application No. 61/569,946, filed on Dec. 13, 2011.

(51) Int. Cl. H01L 31/0224

(52) U.S. Cl. 257/459; 257/E31.124

(57) ABSTRACT

A photovoltaic device includes a substrate, the substrate having a base region and an emitter region, the base region having a first width and the emitter region having a second width, a first electrode in contact with and electrically connected to the base region, the first electrode having a third width where it overlies the base region, the third width being greater than the first width such that the first electrode overhangs the base region at at least one side thereof, and a second electrode in contact with and electrically connected to the emitter region, the second electrode having a fourth width where it overlies the emitter region, a ratio of the third width to the fourth width being about 0.3 to about 3.4.

### CROSS-REFERENCE TO RELATED APPLICATION

This application claims priority to pending U.S. Provisional Application No. 61/569,946, filed in the U.S. Patent and Trademark Office on Dec. 13, 2011, and entitled “PHOTOVOLTAIC DEVICE,” which is hereby incorporated by reference herein in its entirety for all purposes.

### BACKGROUND

1. Field

Embodiments relate to a photovoltaic device.

2. Description of Related Art

In a photovoltaic device, a p-n junction may be formed by doping an n-type (or p-type) dopant into a p-type (or n-type) substrate so as to form an emitter. In operation of such a device, electron-hole pairs (formed by received light) are separated. Then, electrons may be collected by an electrode of an n-type area and holes may be collected by an electrode of a p-type area, thereby generating electric power.

### SUMMARY

Embodiments are directed to a photovoltaic device, including a substrate, the substrate having a base region and an emitter region, the base region having a first width and the emitter region having a second width, a first electrode in contact with and electrically connected to the base region, the first electrode having a third width where it overlies the base region, the third width being greater than the first width such that the first electrode overhangs the base region at least one side thereof, and a second electrode in contact with and electrically connected to the emitter region, the second electrode having a fourth width where it overlies the emitter region, a ratio of the third width to the fourth width being about 0.3 to about 3.4.

The ratio of the third width to the fourth width may be about 0.4 to about 2.5.

The substrate may include a plurality of base regions and a plurality of emitter regions, the base regions and the emitter regions being arranged as alternating stripes, the first electrode may include a plurality of first portions, the first portions of the first electrode respectively corresponding to the base regions, and the second electrode may include a plurality of first portions, the first portions of the second electrode respectively corresponding to the emitter regions.

Each of the first portions of the first electrode may have an upper portion and a lower portion, the upper portion having the third width and the lower portion having a fifth width that is less than the third width, the fifth width corresponding to a contact interface of the lower portion with a corresponding base region, and each of the first portions of the second electrode may have an upper portion and a lower portion, the upper portion having the fourth width and the lower portion having a sixth width that is less than the fourth width, the sixth width corresponding to a contact interface of the lower portion with a corresponding emitter region.

The first portions of the first electrode may be connected by a second portion of the first electrode, and the first portions of the second electrode may be connected by a second portion of the second electrode.

The first portions of the first electrode may be interspersed with the first portions of the second electrode.

The base region may be doped with an impurity of a first conductivity type, the emitter region may be doped with an impurity of a second conductivity type, and the substrate may be doped with an impurity of the same conductivity type as the base region.

The base and emitter regions may be formed in the substrate or the base and emitter regions may be formed on the substrate.

A lateral portion of the first electrode that overhangs the base region may also overlap a portion of an adjacent emitter region.

The second width may be greater than the first width.

The photovoltaic device may further include an insulating layer interposed between the lateral portion of the first electrode and the portion of the adjacent emitter region.

The insulating layer may include a first layer and a second layer.

The first layer and the second layer may be formed of different materials.

The first layer may be formed of silicon oxide or silicon nitride, and the second layer may be formed of a polymer.

The first layer may have a thickness of about 500 Å to about 3000 Å, and the second layer may have a thickness of about 0.5 μm to about 30 μm.

The first layer may be formed of silicon oxide or silicon nitride, and the second layer may be formed of silicon oxide or silicon nitride.

The first layer may have a thickness of about 500 Å to about 3000 Å, and the second layer may have a thickness of about 500 Å to about 3000 Å.

The insulating layer may be a monolayer having a thickness of about 8000 Å or more.

The first electrode may contact the base region via a contact hole in the insulating layer, and the second electrode may contact the emitter region via another contact hole in the insulating layer.

A front surface of the substrate, opposite the electrodes, may have a passivation layer thereon, the passivation layer being formed of a doped amorphous semiconductor material.

### BRIEF DESCRIPTION OF THE DRAWINGS

Features will become apparent to those of skill in the art by describing in detail exemplary embodiments with reference to the attached drawings in which:

FIG. 1 illustrates a schematic perspective view of a photovoltaic device according to an example embodiment, and FIG. 2 illustrates a cross-sectional view taken along line II-II of FIG. 1.

FIG. 3 illustrates a conceptual schematic diagram for explaining a width ratio C.

FIG. 4 illustrates a graph showing a series resistance according to a width ratio of a first electrode and a second electrode.

FIGS. 5 through 7 illustrate schematic cross-sectional views of photovoltaic devices according to other example embodiments.

FIGS. 8A through 12 illustrate schematic cross-sectional views of stages in a method of manufacturing a photovoltaic device according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of exemplary embodiments. As used herein, the singular forms “a/an” and “the” are intended to include the plural forms (a plurality of) as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof. The terms such as “first” and “second” are used herein merely to describe a variety of constituent elements, but the constituent elements are not limited by the terms. The terms are used only for the purpose of distinguishing one constituent element from another constituent element.

In the drawings, the thicknesses of layers, regions, and films may be exaggerated for clarity. It will also be understood that when a layer is referred to as being “on” another layer or substrate, it can be “directly on” the other layer or substrate, or intervening layers may also be present. Conversely, when a constituent element is described to be “directly on” another constituent element, the constituent element should be construed to be directly connected to another constituent element without any other constituent element interposed therebetween. Like reference numerals refer to like elements throughout.

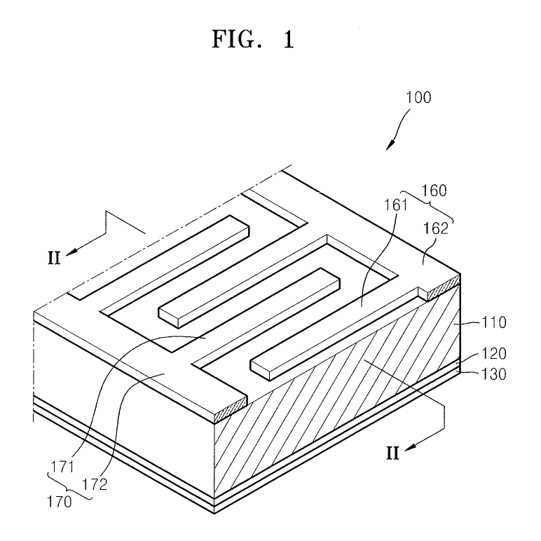

FIG. 1 illustrates a schematic perspective view of a photovoltaic device according to an example embodiment, and FIG. 2 illustrates a cross-sectional view taken along line II-II of FIG. 1.

Referring to FIGS. 1 and 2, the photovoltaic device 100 according to the present example embodiment may include a semiconductor substrate 110, a passivation layer 120 and an anti-reflection layer 130 formed on a first surface of the semiconductor substrate 110, a base region 140 and an emitter region 150 formed in a second surface of the semiconductor substrate 110, a first electrode 160 electrically connected to the base region 140, and a second electrode 170 electrically connected to the emitter region 150. An insulation layer 180, including a first insulation layer 181 and a second insulation layer 182, may be provided between the base and emitter regions 140 and 150 and the first and second electrodes 160 and 170.

The semiconductor substrate 110 may be formed of crystal silicon or a compound semiconductor. For example, a silicon wafer may be used as the semiconductor substrate 110. The semiconductor substrate 110 may be doped with an n-type impurity or a p-type impurity. The p-type impurity may be a Group III compound such as boron (B) and aluminum (Al). The n-type impurity may be a Group V compound such as phosphorus (P).

The semiconductor substrate 110 may have a first surface and a second surface that is opposite to the first surface. The first surface may be a light-receiving surface and emitter and base electrodes (first and second electrodes 160 and 170) may be provided on the second surface.

The passivation layer 120 may be provided on the first surface of the semiconductor substrate 110 and may improve the efficiency of collection of carriers by preventing surface recombination of carriers generated by the semiconductor substrate 110. For example, the passivation layer 120 may prevent the carriers from moving to the first surface of the semiconductor substrate 110 so that electrons and holes may be prevented from being recombined at and near the first surface of the semiconductor substrate 110. The passivation layer 120 may be, e.g., an intrinsic semiconductor layer or a doped semiconductor layer. In an implementation, the passivation layer 120 may be formed as, e.g., a silicon oxide layer or a silicon nitride layer.

When the passivation layer 120 is an intrinsic semiconductor layer or a doped semiconductor layer, the passivation layer 120 may be formed of amorphous silicon deposited on the semiconductor substrate 110. For example, the passivation layer 120 may be formed of amorphous silicon doped in a first conductive type that is the same as the semiconductor substrate 110. The passivation layer 120 may be doped at a higher concentration than the semiconductor substrate 110 so as to form a front surface field (FSF) for preventing the surface recombination.

The anti-reflection layer 130 may be formed on the passivation layer 120. The anti-reflection layer 130 may prevent light absorption loss of the photovoltaic device 100 due to reflection of light when sunlight is incident, so that the efficiency of the photovoltaic device 100 may be improved. The anti-reflection layer 130 may be formed as, e.g., a silicon oxide layer or a silicon nitride layer. For example, the anti-reflection layer 130 may be formed as a single silicon oxide layer, or as a combined layer including a silicon oxide layer and a silicon nitride layer having different refractive indexes.

In the present example embodiment the passivation layer 120 and the anti-reflection layer 130 are formed as separate layers. In another embodiment, the passivation layer 120 and the anti-reflection layer 130 may be formed as one layer. For example, a single silicon nitride layer may be formed so that the effects of passivation and anti-reflection may be simultaneously obtained.

The base region 140 and the emitter region 150 may be formed in the second surface of the semiconductor substrate 110. The base region 140 and the emitter region 150 may be alternately formed. For example, the base region 140 and the emitter region 150 may be formed in a striped pattern and parallel to each other. The emitter region 150 may be formed to have a width larger than that of the base region 140. In an implementation, the width W2 of the emitter region 150 is formed greater than the width W1 of the base region 140 so that a short-circuit current Jsc may be increased.

The base region 140 may be doped with the same impurity type as the semiconductor substrate 110. The emitter region 150 may be doped with an impurity type different from the semiconductor substrate 110. For example, when the semiconductor substrate 110 includes an n-type impurity, the base region 140 as an n+ region may include a lot of n-type impurities so that the generated electrons may be easily collected at the first electrode 160, and the emitter region 150 as a p+ region may include a lot of p-type impurities so that the generated holes may be easily collected at the second electrode 170. In another embodiment, the base region 140 may be a p+ region, whereas the emitter region 150 may be an n+ region.

The first electrode 160 may include a first bus bar 162 and a plurality of first finger electrodes 161 that are formed perpendicular to the first bus bar 162 in a comb-like arrangement. The first finger electrodes 161 may be arranged on the base region 140 to collect carriers. The first bus bar 162 may be connected to the first finger electrodes 161 to transfer the carriers collected by the first finger electrodes 161 to the outside. The first electrode 160 may be formed of silver (Ag), gold (Au), copper (Cu), aluminum (Al), nickel (Ni), or a combination thereof. In an implementation the first finger electrodes 161 and the first bus bar 162 may be integral.

The second electrode 170 may include a second bus bar 172 and a plurality of second finger electrodes 171 that are formed perpendicular to the second bus bar 172 in a comb-like arrangement. The second finger electrodes 171 may be arranged on the emitter region 150 to collect carriers. The second bus bar 172 may be connected to the second finger electrodes 171 to transfer the carriers collected by the second finger electrodes 171 to the outside. The second electrode 170 may be formed of silver (Ag), gold (Au), copper (Cu), aluminum (Al), nickel (Ni), or a combination thereof. In an implementation, the second finger electrodes 171 and the second bus bar 172 may be integral.

The first and second finger electrodes 161 and 171 may be alternately formed, and the alternating base and emitter regions 140 and 150 may form an interdigitated structure with the first and second finger electrodes 161 and 171 thereon. The first electrode 160, in detail, the first finger electrodes 161, may be electrically connected to the base region 140. The second electrode 170, in detail, the second finger electrodes 171, may be electrically connected to the emitter region 150.

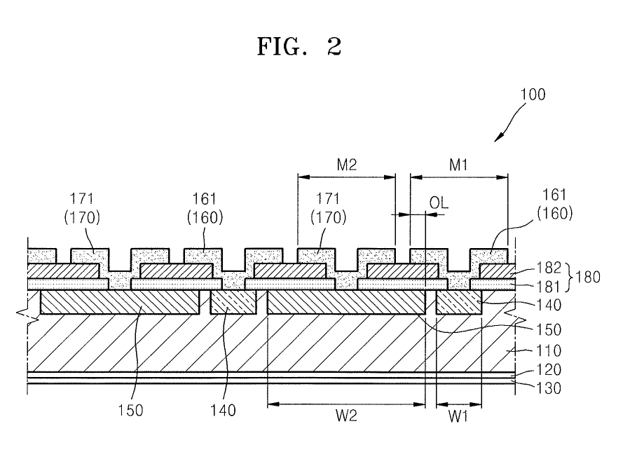

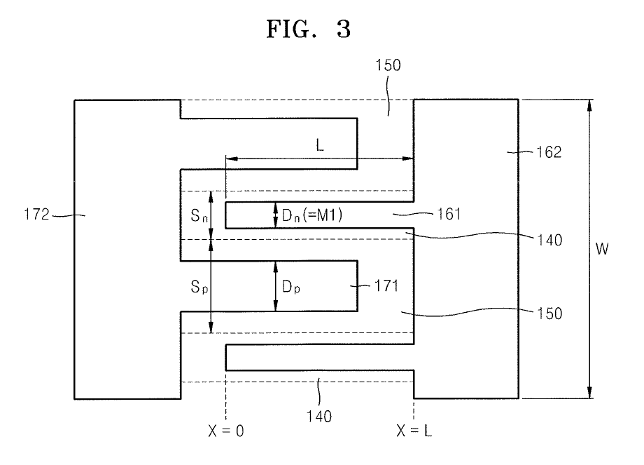

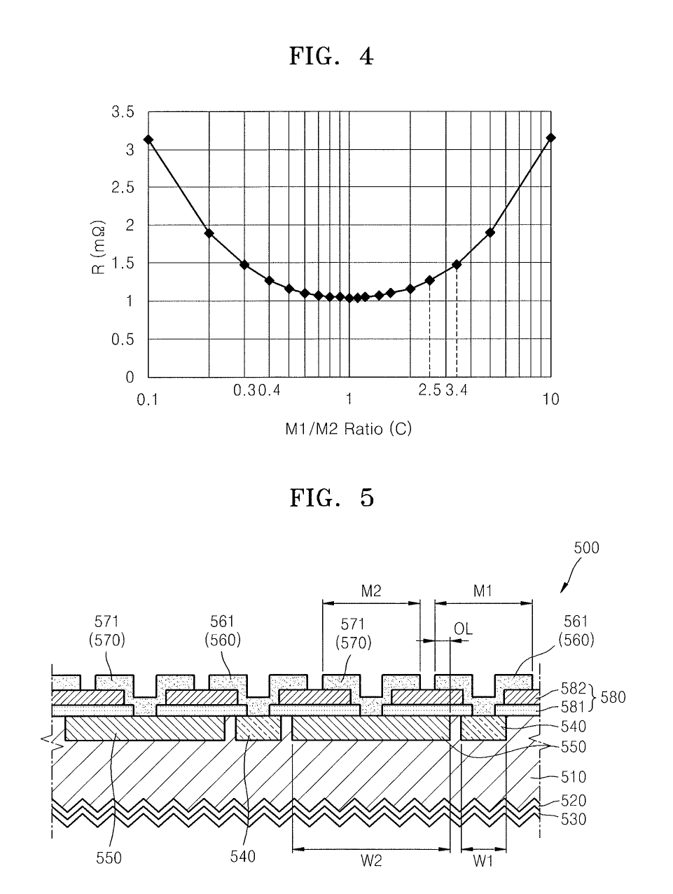

A ratio C (C=M1/M2) between a width M1 of each of the first finger electrodes 161 and a width M2 of each of the second finger electrodes 171 may be in a range of about 0.3 to about 3.4. In detail, the width ratio C may be in a range of about 0.4 to about 2.5. In an embodiment, the width ratio C may be 1.0 so that the width M1 of each of the first finger electrodes 161 and the width M2 of each of the second finger electrodes 171 may have substantially the same value. A detailed description on the width ratio C will be presented below with reference to FIGS. 3 and 4.

The width M1 of each of the first finger electrodes 161 may be formed to be larger than the width W1 of the base region 140. The width M2 of each of the second finger electrodes 171 may be formed to be less than the width W2 of the emitter region 150. Since the width M1 of each of the first finger electrodes 161 is formed larger than the width W1 of the base region 140, there may be a region OL where the first finger electrode 161 overlaps with the emitter region 150. Since the second finger electrode 171 and the emitter region 150 in the overlap region OL have opposite conduction types, a shunt may occur and the insulation layer 180 is provided to prevent the shunt.

In the present embodiment, and in embodiments described elsewhere in this disclosure, a width of the overlap region OL may be described as OL≦(M1−W1)/2. As discussed above, the insulation layer 180 may be located between the emitter region 150 and the base electrodes (first and second electrodes 160 and 170) to prevent a shunt. However, the possibility of a shunt occurring between the emitter region 150 and base electrode may increase as the value of OL increases. In order to minimize this possibility and prevent a reduction of efficiency of the photovoltaic device, M1 may be decreased. For example, the possibility of a shunt may be lowered under the condition that M1<M2.

The insulation layer 180 may include the first and second insulation layers 181 and 182. The first and second insulation layers 181 and 182 may be formed on the base region 140 and the emitter region 150 and under the first and second electrodes 160 and 170, thereby preventing a shunt between constituent elements having opposite conduction types. The first and second insulation layers 181 and 182 may include via holes via which the first and second electrodes 160 and 170 may directly contact the base region 140 and the emitter region 150, respectively. The first electrode 160 may be electrically connected to the base region 140 through the via hole. The second electrode 170 may be electrically connected to the emitter region 150 through the via hole.

The first and second insulation layers 181 and 182 may be formed as, e.g., a silicon oxide (SiOₓ) layer or a silicon nitride (SiNₓ) layer. For example, the first insulation layer 181 may be formed as a silicon oxide layer and the second insulation layer 182 may be formed as a silicon nitride layer. In another implementation, the first insulation layer 181 may be formed as a silicon nitride layer and the second insulation layer 182 may be formed as a silicon oxide layer. The first and second insulation layers 181 and 182 each may be formed to have a thickness of about 500 Å to about 3000 Å.

In another example embodiment, the first insulation layer 181 may be formed as a silicon oxide (SiOₓ) layer or a silicon nitride (SiNₓ) layer and the second insulation layer 182 may be formed of polyimide. Alternatively, the second insulation layer 182 may be formed of ethylenevinylacetate (EVA), polyethylene terephthalate (PET), or polycarbonate (PC). The first insulation layer 181 may be formed to have a thickness of about 500 Å to about 3000 Å, and the second insulation layer 182 may be formed to have a thickness of about 0.5 μm to about 30 μm.

In the photovoltaic device 100 according to the present example embodiment, the width W2 of the emitter region 150 is formed larger than that of the base region 140 to increase a short-circuit current Jsc. Also, to reduce the series resistance, the first and second electrodes 160 and 170, in detail, the first and second finger electrodes 161 and 171, are formed to have an appropriate width ratio C therebetween. When the width ratio C of the first and second finger electrodes 161 and 171 is out of a predetermined range, the resistance of one or both of the first and second finger electrodes 161 and 171 may be increased, which may cause an overall efficiency of the photovoltaic device 100 to be reduced.

The ratio C between the widths M1 and M2 of the first and second finger electrodes 161 and 171 of the photovoltaic device 100 according to the present example embodiment (C=M1/M2) will now be described with reference to FIGS. 3 and 4.

FIG. 3 illustrates a conceptual schematic diagram for explaining the width ratio C. FIG. 4 illustrates a graph showing a series resistance R is shown according to the width ratio C (=M1/M2) of a first electrode and a second electrode.

Although in FIG. 3 the number of first and second finger electrodes 161 and 171 is two, this is a mere illustration of a portion of the photovoltaic device 100 and the number of first and second finger electrodes 161 and 171 is not limited thereto.

Parameters in FIG. 3 are as follows.

Dn: the width of the first finger electrode 161, Dn=M1

Dp: the width of the second finger electrode 171, Dp=M2

Sn: the width of the base region 140, Sn=W1

Sp: the width of the emitter region 150, Sp=W2

Nn: the number of first finger electrodes 161

Np: the number of second finger electrodes 171

L: the length of each of the finger and second electrodes 161 and 171, L>>Dn, Dp

W: the width of the photovoltaic device 100

Accordingly, W=Sn×(Number of base regions)+Sp×(Number of emitter regions)

Cell pitch: Sn+Sp

Power loss Pn by the first finger electrode 161 having a length L can be expressed by Equation (1):

$${P}_{n} = \int {i}^{2} d {r}_{n} = {\int }_{0}^{L} {( {J}_{n} {s}_{n} x )}^{2} \frac{ρ}{{D}_{n} t} d x = \frac{{J}_{n}^{2} {s}_{n}^{2} ρ {L}^{3}}{3 {D}_{n} t} \qquad ( 1 )$$

When the number of first and second finger electrodes 161 and 171 is the same, that is,

$${N}_{n} = {N}_{p} = \frac{N}{2} ,$$

the total power loss P can be expressed by Equation (2):

$$P = ( {P}_{n} + {P}_{p} ) \frac{N}{2} = \frac{ρ {L}^{3} N}{6 t} ( \frac{{J}_{n}^{2} {s}_{n}^{2}}{{D}_{n}} + \frac{{J}_{p}^{2} {s}_{p}^{2}}{{D}_{p}} ) \\ {J}_{n} = \frac{{I}_{mp}}{L {s}_{n} ( N / 2 )} , {J}_{p} = \frac{{I}_{mp}}{L {s}_{p} ( N / 2 )} \\ However , \qquad ( 2 )$$

The total power loss P of the photovoltaic device 100 can be expressed by Iₙₚ²R. At this time, the total power loss P of Equation (2) can be expressed by Equation (3):

$$\frac{ρ {L}^{3} N}{6 t} ( \frac{{[ \frac{{I}_{mp}}{L {s}_{n} ( N / 2 )} ]}^{2} {s}_{n}^{2}}{{D}_{n}} + \frac{{[ \frac{{I}_{mp}}{L {s}_{p} ( N / 2 )} ]}^{2} {s}_{p}^{2}}{{D}_{p}} ) = {I}_{mp}^{2} R \qquad ( 3 )$$

When Equation (3) is summarized, Equation (4) is obtained:

$$R = \frac{2 ρ L}{3 tN} ( \frac{1}{{D}_{n}} + \frac{1}{{D}_{p}} ) \qquad ( 4 )$$

A metal coverage k, that is an area ratio of the first and second finger electrodes 161 and 171 to the second surface of the photovoltaic device 100, can be expressed by Equation (5):

$$k = \frac{( {D}_{n} + {D}_{p} ) L \frac{N}{2}}{WL} \qquad ( 5 )$$

When Equation (5) is solved for the series resistance R, Equation (6) is obtained:

$$R = \frac{ρ L}{ 3 t k W} \frac{{( {D}_{n} + {D}_{p} )}^{2}}{( {D}_{n} {D}_{p} )} \qquad ( 6 )$$

When Dₚ=CDₙ is substituted in Equation (6), Equation (7) is obtained:

$$R = \frac{ρ L}{ 3 t k W} \frac{{( C + 1 )}^{2}}{C} \qquad ( 7 )$$

A value of the series resistance R according to the width ratio C value (M1/M2, Dn/Dp) based on Equation (7) is presented in a graph of FIG. 4. Referring to the FIG. 4, the series resistance R has a minimum value when C=1 as shown in Equation (8), and the graph of the series resistance R is bilaterally symmetrical about a point where C=1.

$${R}_{min} = \frac{4 ρ L}{ 3 t k W} when C = 1 \qquad ( 8 )$$

Referring to FIG. 4, the ratio C of the widths M1 and M2 of the first and second finger electrodes 161 and 171 may have a ratio of about 0.3 to about 3.4. If the width ratio C is less than about 0.3 or exceeds about 3.4, it can be seen from FIG. 4 that the series resistance R may significantly increase. That is, if the width ratio C exceeds a range of about 0.3≦C≦3.4, the series resistance R may increase so that an overall efficiency of the photovoltaic device 100 may be deteriorated.

In an implementation, the ratio C of the widths M1 and M2 of the first and second finger electrodes 161 and 171 may have a ratio of about 0.4 to 2.5. Considering a drop rate of a fill factor based on a value of the fill factor when C=1, the width ratio C may have a range of about 0.4≦C≦2.5. This is illustrated in detail with reference to Table 1:

TABLE 1

| C | R (mΩ) | F.F. drop (%) |
|---|---|---|
| 0.1 | 3.142857 | 2.12 |
| 0.2 | 1.897861 | 1.64 |
| 0.3 | 1.478992 | 1.28 |
| 0.4 | 1.270997 | 1.1 |
| 0.5 | 1.16359 | 1.01 |
| 0.6 | 1.105569 | 0.96 |
| 0.7 | 1.070911 | 0.93 |
| 0.8 | 1.051474 | 0.91 |
| 0.9 | 1.051474 | 0.91 |
| 1 | 1.038961 | 0.9 |
| 1.1 | 1.042061 | 0.9 |
| 1.2 | 1.051474 | 0.91 |
| 1.4 | 1.070911 | 0.93 |
| 1.6 | 1.105569 | 0.96 |
| 2 | 1.16359 | 1.01 |
| 2.5 | 1.270997 | 1.1 |
| 3.4 | 1.478992 | 1.28 |
| 5 | 1.897861 | 1.64 |
| 10 | 3.142857 | 2.72 |

Table 1 shows a fill factor and a series resistance R according to a width ratio C value in the photovoltaic device 100 according to the present example embodiment. In the photovoltaic device 100 according to the present example embodiment, the first and second finger electrodes 161 and 171 are formed to have the same widths and include copper with a thickness of about 35 μm and a cell pitch of about 1500 μm.

Referring to Table 1, in the photovoltaic device 100 having a cell pitch of about 1500 μm, a drop rate of a fill factor (F.F. drop) when C=1, that is, M1=M2, is about 0.9%. Considering an error range of about ±10% for the F.F. drop when C=1, C may have a range of 0.4≦C≦2.5.

FIGS. 5 through 7 illustrate schematic cross-sectional views of photovoltaic devices according to other example embodiments.

FIG. 5 illustrates a schematic cross-sectional view of a photovoltaic device 500 according to another example embodiment.

Referring to FIG. 5, the photovoltaic device 500 according to the present example embodiment may include a semiconductor substrate 510, a passivation layer 520, and an anti-reflection layer 530 formed on a first surface of the semiconductor substrate 510, a base region 540 and an emitter region 550 formed on a second surface of the semiconductor substrate 510, a first electrode 560 electrically connected to the base region 540, and a second electrode 570 electrically connected to the emitter region 550. An insulation layer 580, including a first insulation layer 581 and a second insulation layer 582, may be provided between the base and emitter regions 540 and 550 and the first and second electrodes 560 and 570.

In the photovoltaic device 500 according to the present example embodiment, the base region 540 and the emitter region 550 may be formed in a striped pattern and parallel to each other. The emitter region 550 may be formed to have a width larger than that of the base region 540. In an implementation, the width W2 of the emitter region 550 may be formed greater than the width W1 of the base region 540 so that a short-circuit current Jsc may be increased.

The width M1 of each of the first finger electrodes 561 may be greater than the width W1 of the base region 540. The width M2 of each of the second finger electrodes 571 may be less than the width W2 of the emitter region 550. The width M1 of each of the first finger electrodes 561 may be formed greater than the width W1 of the base region 540. Thus, a region OL where the first finger electrode 561 overlaps with the emitter region 550 may be formed.

A ratio C (C=M1/M2) between the width M1 of each of the first finger electrodes 561 and the width M2 of each of the second finger electrodes 571 may be in a range of about 0.3 to about 3.4. In an implementation, the width ratio C may be in a range of about 0.4 to about 2.5. In an embodiment, the width ratio C may be about 1.0 so that the width M1 of each of the first finger electrodes 561 and the width M2 of each of the second finger electrodes 571 may have substantially the same value.

The photovoltaic device 500 according to the present example embodiment is different from the photovoltaic device 100 of FIG. 2 in terms of the shape of a light-receiving surface. For convenience of explanation, only a difference between the embodiments will now be described below and repeated descriptions are omitted.

A first surface of the semiconductor substrate 510 may be surface-textured. The semiconductor substrate 510 that is surface-textured may include an uneven pattern, for example, a pyramid or honeycomb shape. The semiconductor substrate 510 that is surface-textured has an increased surface area so as to increase a light absorption rate and decrease a reflection rate, thereby improving the efficiency of the photovoltaic device 500.

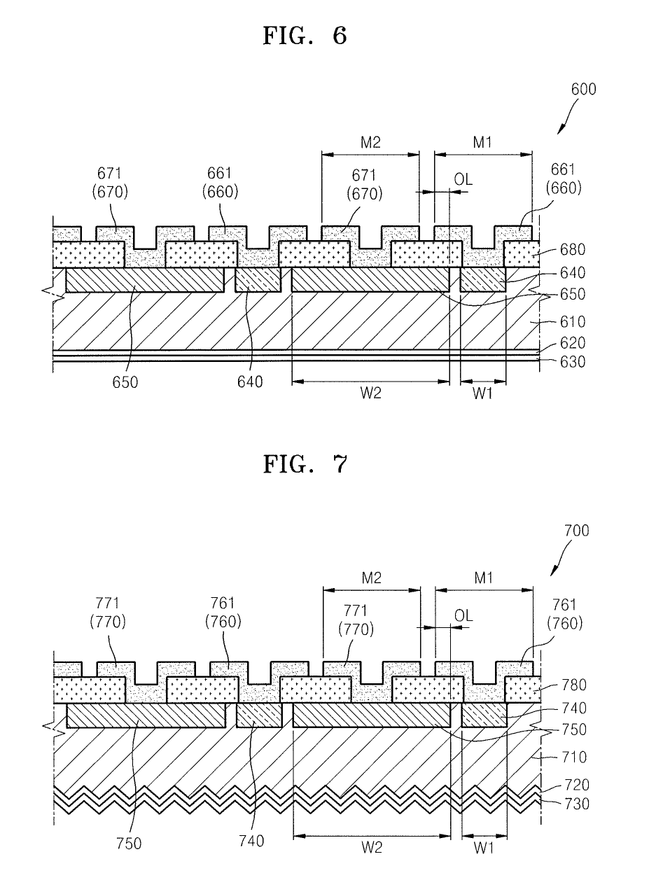

FIGS. 6 and 7 illustrate schematic cross-sectional views of photovoltaic devices 600 and 700 according to other example embodiments.

Referring to FIG. 6, the photovoltaic device 600 according to the present example embodiment may include a semiconductor substrate 610, a passivation layer 620, and an anti-reflection layer 630 formed on a first surface of the semiconductor substrate 610, a base region 640 and an emitter region 650 formed on a second surface of the semiconductor substrate 610, a first electrode 660 electrically connected to the base region 640, and a second electrode 670 electrically connected to the emitter region 650. An insulation layer 680 may be between the base and emitter regions 640 and 650 and the first and second electrodes 660 and 670.

In the photovoltaic device 600 according to the present example embodiment, the base region 640, and the emitter region 650 may be formed in a striped pattern and parallel to each other. The width W2 of the emitter region 650 is formed greater than the width W1 of the base region 640. The width W2 of the emitter region 650 may be formed greater than the width W1 of the base region 640. Thus, a short-circuit current Jsc may be increased.

The width M1 of each of the first finger electrodes 661 may be greater than the width W1 of the base region 640. The width M2 of each of the second finger electrodes 671 may be less than the width W2 of the emitter region 650. The width M1 of the first finger electrode 661 may be formed greater than the width W1 of the base region 640. Thus, a region OL (where the first finger electrode 661 overlaps with the emitter region 650) may be formed.

A ratio C (C=M1/M2) between the width M1 of each of the first finger electrodes 661 and the width M2 of each of the second finger electrodes 671 may be in a range of about 0.3 to about 3.4. In an implementation, the width ratio C may be in a range of about 0.4 to about 2.5. In an embodiment, the width ratio C may be about 1.0 so that the width M1 of each of the first finger electrodes 661 and the width M2 of each of the second finger electrodes 671 may have substantially the same value.

The photovoltaic device 600 according to the present example embodiment is different from the photovoltaic device 100 of FIG. 2 in that the insulation layer 680 is formed as a single layer. For convenience of explanation, only a difference between the embodiments will now be described and a repeated description is omitted.

The insulation layer 680 may be formed on the base region 640 and the emitter region 650 and under the first and second electrodes 660 and 670, thereby preventing a shunt between constituent elements having opposite conduction types. The insulation layer 680 may include via holes through which the first and second electrodes 660 and 670 directly contact the base region 640 and the emitter region 650, respectively. The first electrode 660 may be electrically connected to the base region 640 through a via hole. The second electrode 670 may be electrically connected to the emitter region 650 through a via hole.

The insulation layer 680 may be formed of, e.g., a silicon oxide layer SiOₓ or a silicon nitride layer SiNₓ. For example, the insulation layer 680 may be formed with a thickness of about 8000 Å or more. A pin hole may be formed in the insulation layer 680 that is formed of a silicon oxide layer and a silicon nitride layer. Where the insulation layer 680 is a single layer, forming the insulation layer 680 with a thickness of about 8000 Å or more may help avoid occurrence of a shunt between the first finger electrodes 661 and the emitter region 650 by way of a pin hole formed in the insulation layer 680.

Referring to FIG. 7, the photovoltaic device 700 according to the present example embodiment may include a semiconductor substrate 710, a passivation layer 720, and an anti-reflection layer 730 formed on a first surface of the semiconductor substrate 710, a base region 740 and an emitter region 750 formed on a second surface of the semiconductor substrate 710, a first electrode 760 electrically connected to the base region 740, and a second electrode 770 electrically connected to the emitter region 750. An insulation layer 780 may be between the base and emitter regions 740 and 750 and the first and second electrodes 770 and 770.

While the other constituent elements are the same as those of the photovoltaic device 600 described with reference to FIG. 6, the photovoltaic device 700 is different from the photovoltaic device 600 of FIG. 6 only in the structure of a first surface of the semiconductor substrate 710.

The first surface of the semiconductor substrate 710 may be surface-textured and may include an uneven pattern such as a pyramid or honeycomb shape. The surface-textured semiconductor substrate 710 may increase a surface area so as to increase a light absorption rate and decrease a reflection rate, and may thus improve the efficiency of the photovoltaic device 700.

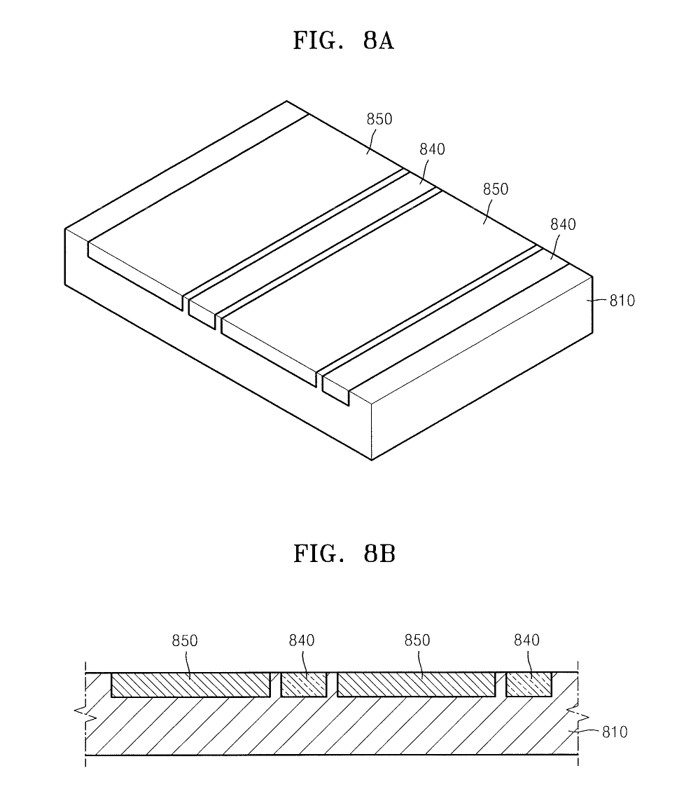

FIGS. 8A through 12 illustrate schematic cross-sectional views of stages in a method of manufacturing a photovoltaic device according to an example embodiment. FIG. 8A illustrates a cross-sectional perspective view of FIG. 8B.

First, a semiconductor substrate 810, for example, a silicon wafer, may be prepared. The semiconductor substrate 810 may be doped with an n-type impurity or p-type impurity.

Referring to FIGS. 8A and 8B, a base region 840 and an emitter region 850 may be formed in a second surface of the semiconductor substrate 810. The base region 840 and the emitter region 850 may be alternately formed. For example, the base region 840 and an emitter region 850 may be formed in a striped pattern and parallel to each other. The width W2 of the emitter region 850 may be greater than the width W1 of the base region 840 to increase a short-circuit current Jsc.

The base region 840 may be doped with impurities of the same type as the semiconductor substrate 810. The emitter region 850 may be doped with impurities of a different type from the semiconductor substrate 810. The impurities for forming the base region 840 and the emitter region 850 may be doped by a method such as an ion implant method or a thermal diffusion method.

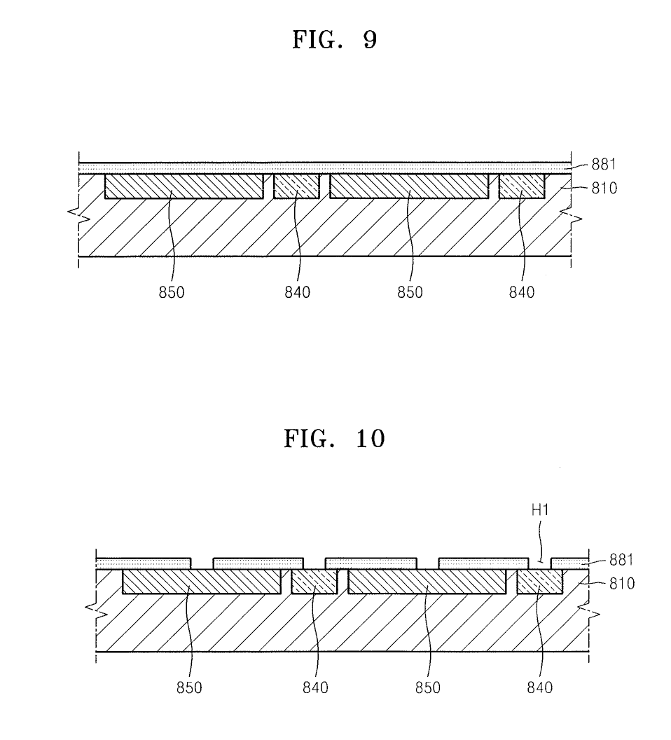

Referring to FIG. 9, a first insulation layer 881 may be formed of, e.g., a silicon oxide layer SiOₓ or a silicon nitride layer SiNₓ. The first insulation layer 881 may be formed by, e.g., a chemical vapor deposition (CVD) method. The first insulation layer 881 may be formed with a thickness of about 500 Å to about 3000 Å.

Referring to FIG. 10, a plurality of first via holes H1 may be formed in the first insulation layer 881. For example, after an etch prevention layer (not shown) is formed on the first insulation layer 881 that is formed according to the process described with reference to FIG. 9, a plurality of first via holes H1 may be formed by etching regions that are not protected by the etch prevention layer.

Also, in another method, the first via holes H1 may be formed by using etching paste. For example, etching paste may be coated by a screen print method at locations where the first via holes H1 are to be formed. Next, a part of the first insulation layer 881 where the etching paste is formed may be selectively etched by performing heat treatment for a predetermined time, and thus parts of the base region 840 and the emitter region 850 may be exposed.

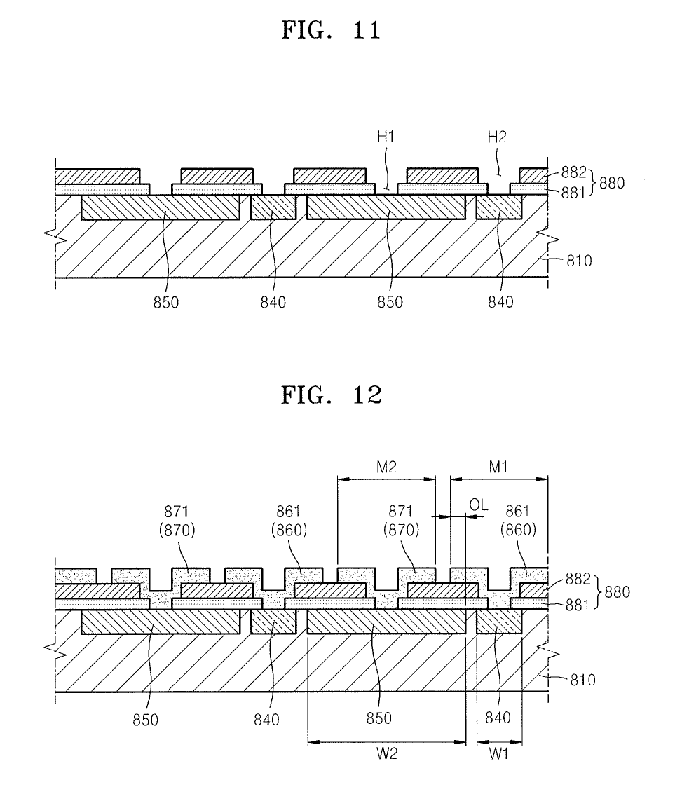

Referring to FIG. 11, a second insulation layer 882 may be formed on the first insulation layer 881. The second insulation layer 882 may include a material such as polyimide, EVA, PET, or PC. The second insulation layer 882 may be formed to have a thickness of about 0.5 μm to about 30 μm. In another embodiment, the second insulation layer 882 may be formed of a silicon oxide layer SiOₓ or a silicon nitride layer SiNₓ. In this case, the second insulation layer 821 may be formed by a CVD method with a thickness of about 500 Å to about 3000 Å. The second insulation layer 882 may include respective second via holes H2 in areas corresponding to the first via holes H1. When the second insulation layer 882 includes a material such as polyimide, the polyimide may be coated, leaving an area corresponding to the second via holes H2 uncoated. At this time, the polyimide may be coated on at least a part of the other area except for the area corresponding to the second via holes H2. In another implementation, when the second insulation layer 882 includes a silicon oxide layer or a silicon nitride layer, the second via holes H2 may be formed as described with reference to FIG. 10.

In the present example embodiment, a case of forming an insulation layer 880 including the first and second insulation layers 881 and 882 has been described with reference to FIGS. 9 through 11. However, the insulation layer 880 may be formed as a single layer. The insulation layer 880 as a single layer may be formed as a silicon oxide layer SiOₓ or a silicon nitride layer SiNₓ. The insulation layer 880 may be formed with a thickness of about 8000 Å to help prevent generation of a shunt due to a pin hole. The formation of a via hole in the insulation layer 880 as a single layer formed as silicon nitride layer or a silicon oxide layer is the same as that described with reference to FIG. 10.

Referring to FIG. 12, first and second electrodes 860 and 870 may be formed. The first and second electrodes 860 and 870 may be formed by printing conductive paste including an element such as silver (Ag), gold (Au), copper (Cu), aluminum (Al), nickel (Ni), etc., through screen printing and then firing the same.

In another embodiment, seed layers (not shown) contacting the base region 840 and the emitter region 850 through the first and second via holes H1 and H2 may be formed. The first and second electrodes 860 and 870 may be formed on the seed layers by, e.g., metal plating.

The width M1 of each of the first finger electrodes 861 may be greater than the width W1 of the base region 840. The width M2 of each of the second finger electrodes 871 may be less than the width W2 of the emitter region 850. The width M1 of each of the first finger electrodes 861 may be formed greater than the width W1 of the base region 840. Thus, a region OL where the first finger electrode 861 overlaps with the emitter region 850 may be formed.

A ratio C (C=M1/M2) between the width M1 of each of the first finger electrodes 861 and the width M2 of each of the second finger electrodes 871 may be in a range of about 0.3 to about 3.4. In an implementation, the width ratio C may be in a range of about 0.4 to about 2.5. In an embodiment, the width ratio C may be about 1.0 so that the width M1 of each of the first finger electrodes 861 and the width M2 of each of the second finger electrodes 871 may have substantially the same value.

Although not illustrated, the first surface of the semiconductor substrate 810 may be surface-textured. The semiconductor substrate 810 that is surface-textured may include an uneven pattern, for example, a pyramid or honeycomb shape. The uneven pattern may be formed by performing, for example, anisotropic etching through wet etching or dry etching using plasma.

Also, although not illustrated, a passivation layer and an anti-reflection layer may be formed on the first surface of the semiconductor substrate 810 that is surface-textured. The passivation layer may be formed as, e.g., an intrinsic semiconductor layer, a doped semiconductor layer silicon oxide layer, or a silicon nitride layer. The anti-reflection layer may be formed as, e.g., a silicon oxide layer or a silicon nitride layer. For example, the anti-reflection layer may be formed of a chemical vapor deposition (CVD) method. The passivation layer and the anti-reflection layer may be formed as a single layer such as a silicon nitride layer that performs both functions of passivation and anti-reflection.

The process of forming the passivation layer and the anti-reflection layer may be performed before performing the process according to FIG. 8A, after performing the process according to FIG. 12, or during the process described with reference to FIGS. 8A to 12.

By way of summation and review, a photovoltaic device may have a structure in which an electrode is provided at each of a front surface, which is a light-receiving surface, and a back surface. When an electrode is provided at the front surface, a light-receiving area is decreased as much as an area of the electrode. To avoid such a decrease in the light-receiving area, a back contact structure (in which electrodes are provided only on a back surface) may be used.

As described above, in a photovoltaic device according to embodiments, the emitter region may be formed to have a larger width than that of the base region so that short-circuit current may be improved, the width ratio C between the first and second finger electrodes is in a range of about 0.3 to about 3.4, e.g., about 0.4 to about 2.5, so that power loss due to the series resistance of the first and second electrodes may be reduced, and an overall efficiency of the photovoltaic device may be improved with an increase of a fill factor. Also, since an area occupied by the first and second metal electrodes on the second surface of the semiconductor substrate may be increased, reflection of light may be induced so that short-circuit current may be improved.

Accordingly, in the photovoltaic device configured as above, even when a cell pitch is formed small to increase the lifetime of a carrier, that is, to reduce the extinction of the carrier, the series resistance of the first and second electrodes may be reduced and a fill factor and short-circuit current may be increased, such that the efficiency of the photovoltaic device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photovoltaic device, comprising:
a substrate, the substrate having a base region and an emitter region, the base region having a first width and the emitter region having a second width;
a first electrode in contact with and electrically connected to the base region, the first electrode having a third width where it overlies the base region, the third width being greater than the first width such that the first electrode overhangs the base region at least one side thereof; and
a second electrode in contact with and electrically connected to the emitter region, the second electrode having a fourth width where it overlies the emitter region, a ratio of the third width to the fourth width being about 0.3 to about 3.4.

2. The photovoltaic device as claimed in claim 1, wherein the ratio of the third width to the fourth width is about 0.4 to about 2.5.

3. The photovoltaic device as claimed in claim 1, wherein:
the substrate includes a plurality of base regions and a plurality of emitter regions, the base regions and the emitter regions being arranged as alternating stripes,
the first electrode includes a plurality of first portions, the first portions of the first electrode respectively corresponding to the base regions, and
the second electrode includes a plurality of first portions, the first portions of the second electrode respectively corresponding to the emitter regions.

4. The photovoltaic device as claimed in claim 3, wherein:
each of the first portions of the first electrode has an upper portion and a lower portion, the upper portion having the third width and the lower portion having a fifth width that is less than the third width, the fifth width corresponding to a contact interface of the lower portion with a corresponding base region, and
each of the first portions of the second electrode has an upper portion and a lower portion, the upper portion having the fourth width and the lower portion having a sixth width that is less than the fourth width, the sixth width corresponding to a contact interface of the lower portion with a corresponding emitter region.

5. The photovoltaic device as claimed in claim 3, wherein the first portions of the first electrode are connected by a second portion of the first electrode, and the first portions of the second electrode are connected by a second portion of the second electrode.

6. The photovoltaic device as claimed in claim 3, wherein the first portions of the first electrode are interspersed with the first portions of the second electrode.

7. The photovoltaic device as claimed in claim 1, wherein the base region is doped with an impurity of a first conductivity type, the emitter region is doped with an impurity of a second conductivity type, and the substrate is doped with an impurity of the same conductivity type as the base region.

8. The photovoltaic device as claimed in claim 1, wherein the base and emitter regions are formed in the substrate or the base and emitter regions are formed on the substrate.

9. The photovoltaic device as claimed in claim 1, wherein a lateral portion of the first electrode that overhangs the base region also overlaps a portion of an adjacent emitter region.

10. The photovoltaic device as claimed in claim 9, wherein the second width is greater than the first width.

11. The photovoltaic device as claimed in claim 9, further comprising an insulating layer interposed between the lateral portion of the first electrode and the portion of the adjacent emitter region.

12. The photovoltaic device as claimed in claim 11, wherein the insulating layer includes a first layer and a second layer.

13. The photovoltaic device as claimed in claim 12, wherein the first layer and the second layer are formed of different materials.

14. The photovoltaic device as claimed in claim 13, wherein the first layer is formed of silicon oxide or silicon nitride, and the second layer is formed of a polymer.

15. The photovoltaic device as claimed in claim 14, wherein the first layer has a thickness of about 500 Å to about 3000 Å, and the second layer has a thickness of about 0.5 μm to about 30 μm.

16. The photovoltaic device as claimed in claim 12, wherein the first layer is formed of silicon oxide or silicon nitride, and the second layer is formed of silicon oxide or silicon nitride.

17. The photovoltaic device as claimed in claim 12, wherein the first layer has a thickness of about 500 Å to about 3000 Å, and the second layer has a thickness of about 500 Å to about 3000 Å.

18. The photovoltaic device as claimed in claim 12, wherein the insulating layer is a monolayer having a thickness of about 8000 Å or more.

19. The photovoltaic device as claimed in claim 12, wherein the first electrode contacts the base region via a contact hole in the insulating layer, and the second electrode contacts the emitter region via another contact hole in the insulating layer.

20. The photovoltaic device as claimed in claim 1, wherein a front surface of the substrate, opposite the electrodes, has a passivation layer thereon, the passivation layer being formed of a doped amorphous semiconductor material.
